(19) United States
(12) Patent Application Publication
(10) Pub. No.: US 2024/0310450 A1
(43) Pub. Date: Sep. 19, 2024

(54) ESTIMATION DEVICE, DIAGNOSTIC DEVICE, ESTIMATION METHOD, AND DIAGNOSIS METHOD

(71) Applicant: GS Yuasa International Ltd., Kyoto-shi, Kyoto (JP)

(72) Inventors: Shuhei SATO, Kyoto (JP); Nan UKUMORI, Kyoto (JP); Ryosuke TAKEHANA, Kyoto (JP)

(21) Appl. No.: 18/576,980

(22) PCT Filed: Jun. 16, 2022
(86) PCT No.: PCT/JP2022/024046

§ 371 Date: Jan. 5, 2024

(30) Foreign Application Priority Data
Jul. 9, 2021 (JP) 2021-114387

(51) Int. Cl. G01R 31/3842; G01R 31/392; G01R 31/396

(52) U.S. Cl. CPC G01R 31/3842; G01R 31/392; G01R 31/396

(57) ABSTRACT

An estimation device includes: an acquisition unit configured to acquire time-series data of a current and a voltage of an energy storage device; an electricity amount calculation unit configured to calculate time-series data of an electricity amount based on the time-series data of the current acquired by the acquisition unit; a generation unit configured to generate a partial charge-discharge profile of the energy storage device based on the time-series data of the acquired voltage and the time-series data of the calculated electricity amount; and an estimation unit configured to estimate an entire discharge characteristic of the energy storage device based on the partial charge-discharge profile.

### CROSS REFERENCE TO RELATED APPLICATIONS

This application is a National Stage Application, filed under 35 U.S.C. § 371, of International Application No. PCT/JP2022/024046, filed Jun. 16, 2022, which international application claims priority to and the benefit of Japanese Application No. 2021-114387, filed Jul. 9, 2021; the contents of both of which as are hereby incorporated by reference in their respective entireties.

### BACKGROUND

### Technical Field

The present invention relates to an estimation device, a diagnostic device, an estimation method, and a diagnosis method.

### Description of Related Art

Energy storage devices have been widely used in uninterruptible power supply devices, DC or AC power supply devices that are included in stabilized power supplies, and the like. In addition, the use of energy storage devices in large-scale power systems that store renewable energy or power generated by existing power generation systems is expanding.

It is known that the deterioration of an energy storage device progresses by repeating charging and discharging of electricity so that a full charge capacity is gradually lowered. Patent document JP-A-2020-20654 discloses a technology of a full charge-discharge system. In the system, some energy storage devices are removed from an energy storage system on which the energy storage devices are mounted. Then, the removed energy storage devices are charged to a full charge state and, thereafter, the energy storage devices are fully discharged at a fixed discharge current, and the capacity of the energy storage devices is measured.

### BRIEF SUMMARY

In a case where a full charge-discharge system is adopted, it is necessary to stop an operation of an energy storage system. Without stopping an operation of an energy storage system, it is also conceivable to use a limited portion (a part of an operation pattern) in which a capacity of an energy storage device can be diagnosed from an operation data (an operation pattern) of an energy storage system. However, in such a method, only a partial discharge characteristic can be obtained and hence, it is difficult to improve the accuracy of a capacity diagnosis.

It is an object of the present invention to provide: an estimation device that estimates an entire discharge characteristic of an energy storage device; a diagnostic device that diagnoses a full charge capacity (or a state of health) of the energy storage device based on the entire discharge characteristic, an estimation method; and a diagnosis method.

According to a first aspect of the present invention, there is provided an estimation device that includes: an acquisition unit configured to acquire time-series data of a current and a voltage of an energy storage device; an electricity amount calculation unit configured to calculate time-series data of an electricity amount based on the time-series data of the current acquired by the acquisition unit; a generation unit configured to generate a partial charge-discharge profile of the energy storage device based on the time-series data of the voltage acquired by the acquisition unit and the time-series data of the electricity amount calculated by the electricity amount calculation unit; and an estimation unit configured to estimate an entire discharge characteristic of the energy storage device based on the partial charge-discharge profile.

According to the above aspect, it is possible to estimate the entire discharge characteristics of the energy storage device at a predetermined time point after the start of the operation without stopping the operation of the energy storage system.

### BRIEF DESCRIPTION OF THE FIGURES

FIG. 1 is a block diagram illustrating the configuration of an estimation device and the configuration of a diagnostic device.

FIG. 2 is a view illustrating the configuration of a remote monitoring system.

FIG. 3 is a block diagram illustrating the configuration of a bank.

FIG. 4 is a diagram illustrating an example of current data.

FIG. 5 is a diagram illustrating an example of voltage data.

FIG. 6 is a diagram illustrating an example of a partial charge-discharge profile.

FIG. 7 is a diagram illustrating an example of correction of a positive electrode monopolar characteristic by a first parameter.

FIG. 8 is a diagram illustrating an example of correction of a positive electrode monopolar characteristic by a second parameter.

FIG. 9 is a diagram illustrating an example of correction of a negative electrode monopolar characteristic by a third parameter.

FIG. 10 is a diagram illustrating a method of estimating a portion corresponding to a partial charge-discharge profile in an entire discharge characteristic.

FIG. 11 is a diagram illustrating a method of estimating an entire discharge characteristic by complementing a portion other than a partial charge-discharge profile.

FIG. 12 is a diagram illustrating entire discharge curves before and after deterioration.

FIG. 13 is a view illustrating a first example of a diagnosis method for a capacity of an energy storage device.

FIG. 14 is a view illustrating a second example of a diagnosis method for a capacity of an energy storage device.

FIG. 15 is a diagram illustrating a result of a diagnostic capacity.

FIG. 16 is a flowchart illustrating an example of processing steps of an estimation device.

FIG. 17 is a flowchart illustrating an example of processing steps of a diagnostic device.

FIG. 18 is a diagram illustrating an example of electricity amount-voltage plots.

FIG. 19 is a diagram illustrating an example of divided regions.

FIG. 20 is a diagram illustrating a first example of a method of calculating a representative electricity amount and a representative voltage of a divided region.

FIG. 21 is a diagram illustrating an example of a partial charge-discharge profile in a required period.

FIG. 22 is a diagram illustrating a second example of a method of calculating a representative electricity amount and a representative voltage of a divided region.

FIG. 23 is a diagram illustrating an example of generation of a partial charge-discharge profile in a continuous period over a plurality of continuous required periods.

FIG. 24 is a flowchart illustrating processing steps for generating a partial charge-discharge profile according to a second embodiment.

### DETAILED DESCRIPTION OF VARIOUS EMBODIMENTS

An estimation device includes: an acquisition unit configured to acquire time-series data of a current and a voltage of an energy storage device; an electricity amount calculation unit that configured to calculate time-series data of an electricity amount based on the time-series data of the current acquired by the acquisition unit; a generation unit configured to generate a partial charge-discharge profile of the energy storage device based on the time-series data of the voltage acquired by the acquisition unit and the time-series data of the electricity amount calculated by the electricity amount calculation unit; and an estimation unit configured to estimate an entire discharge characteristic of the energy storage device based on the partial charge-discharge profile.

An estimation method includes: a step of acquiring time-series data of a current and a voltage of an energy storage device; a step of calculating time-series data of an electricity amount based on the acquired time-series data of the current; a step of generating a partial charge-discharge profile of the energy storage device based on the acquired time-series data of the voltage and the calculated time-series data of the electricity amount; and estimating an entire discharge characteristic of the energy storage device based on the partial charge-discharge profile.

The acquisition unit of the estimation device acquires time-series data of a current and a voltage of the energy storage device. The time-series data of the current and the voltage is data at the time of charging electricity to the energy storage device or at the time of discharging electricity from the energy storage device. It is not necessary that the charge current or the discharge current is constant. An SOC (state of charge) region and a voltage region during charging electricity and the SOC region and the voltage region during discharging electricity may be limitative. The acquisition unit acquires time-series data in an actual operation pattern (neither an operation stop state nor a specific operation state for a capacity diagnosis) of the energy storage devices. The time-series data may be real-time data or past history data.

The electricity amount calculation unit calculates time-series data of an electricity amount based on the acquired time-series data of a current. An electricity amount can be obtained by current integration. For example, an electricity amount Q (t) can be calculated by an equation {Q (t)=ΣI (t)·Δt}.

The generation unit generates a partial charge-discharge profile of the energy storage device based on the time-series data of an acquired voltage and the time-series data of a calculated electricity amount. For example, a partial charge-discharge profile can be drawn, for example, by plotting time-series data on an electricity amount and a voltage on a two-dimensional coordinate where an electricity amount is taken on an axis of abscissas and a voltage is taken on an axis of ordinates. The partial charge-discharge profile uses the term “partial” to distinguish the partial charge-discharge profile from the entire discharge characteristic. That is, the partial charge-discharge profile is a part of the charge-discharge profile between an upper limit voltage and a lower limit voltage set with respect to the energy storage device or a part of the charge-discharge profile between an upper limit SOC and a lower limit SOC set with respect to the energy storage device.

The estimation unit estimates an entire discharge characteristic of the energy storage device based on the partial charge-discharge profile. The estimation unit may estimate an entire discharge characteristic of the energy storage device based on a positive electrode monopolar characteristic and a negative electrode monopolar characteristic of the energy storage device and a partial charge-discharge profile. The positive electrode monopolar characteristic is a characteristic indicated by a positive electrode discharge curve. The positive electrode discharge curve may be obtained by plotting electricity amounts and potentials corresponding to the electricity amounts on a diagram where an electricity amount is taken on an axis of abscissas and a potential is taken on an axis of ordinates. The negative electrode monopolar characteristic is a characteristic indicated by a negative electrode discharge curve. The negative electrode discharge curve may be obtained by plotting electricity amounts and potentials corresponding to the electricity amounts on a diagram where an electricity amount is taken on an axis of abscissas and a potential is taken on an axis of ordinates. The difference between a potential of the positive electrode and a potential of the negative electrode becomes a voltage of the energy storage device. The entire discharge characteristic may be, for example, a characteristic indicated by a continuous discharge curve between an upper limit voltage and a lower limit voltage set for the energy storage device, or a characteristic indicated by a continuous discharge curve between an upper limit SOC and a lower limit SOC set for the energy storage device.

The estimation unit adjusts at least one of the positive electrode monopolar characteristic and the negative electrode monopolar characteristic of the energy storage device such that a difference between the positive electrode monopolar characteristic and the negative electrode monopolar characteristic of the energy storage device approaches (approximates) a partial charge-discharge profile. An entire discharge characteristic can be estimated from the difference between the positive electrode monopolar characteristic and the negative electrode monopolar characteristic after these monopolar characteristics are adjusted.

With the above-described configuration, it is possible to estimate the entire discharge characteristic of the energy storage device based on the time-series data of a current and a voltage obtained in an actual operation pattern without stopping an operation of the energy storage system or without operating the energy storage system in accordance with a specific operation pattern for a capacity diagnosis.

The estimation device may include a correction unit configured to correct the positive electrode monopolar characteristic and/or the negative electrode monopolar characteristic such that a difference between the positive electrode monopolar characteristic and the negative electrode monopolar characteristic approaches the partial charge-discharge profile. The correction unit may be a part of the estimation unit.

The correction unit corrects, for example, the effectiveness (utilization factor) of the positive electrode. The correction of the effectiveness corresponds to correcting an index indicating a usable amount of an active material in the positive electrode. The correction unit corrects the capacity at the discharge start position of the positive electrode monopolar characteristic. Specifically, the capacity at the discharge start position can be corrected by translating the positive electricity discharge curve along the axis indicating the capacity. The correction of the discharge start position corresponds to the correction of an index indicating oxidative decomposition of an electrolytic solution.

The correction unit corrects the capacity at the discharge start position of the negative electrode monopolar characteristic. Specifically, the correction can be performed by translating the negative electrode discharge curve along the axis indicating the capacity. The correction of the discharge start position corresponds to an index that indicates the growth of a solid electrolyte interface (SEI) film.

With the provision of the above-described configuration, it is possible to bring the difference between a positive electrode monopolar characteristic and a negative electrode monopolar characteristic close to a partial charge-discharge profile.

The estimation device may further include a complement unit that complements the partially obtained entire discharge characteristic of the energy storage device.

The complement unit can complement a portion of the entire discharge characteristic other than the partial charge-discharge profile. The complement unit may be a part of the estimation unit.

The estimation unit can estimate the entire discharge characteristic by connecting the discharge characteristic corresponding to the partial charge-discharge profile and the complemented discharge characteristics.

The estimation device may further include: a plot generation unit that generates electricity amount-voltage plots of the energy storage device over a required period based on time-series data of a voltage acquired by the acquisition unit and time-series data of an electricity amount calculated by the electricity amount calculation unit; and a representative value calculation unit that calculates a representative electricity amount and a representative voltage representing an electricity amount and a voltage in each of divided regions obtained by dividing the electricity amount-voltage plots generated by the plot generation unit by a predetermined electricity amount width, in which the generation unit generates a partial charge-discharge profile for the required period based on the representative electricity amount and the representative voltage for each of the divided regions calculated by the representative value calculation unit.

The plot generation unit may generate electricity amount-voltage plots of the energy storage device over a required period. The electricity amount-voltage plots can be drawn, for example, by plotting time-series data on an electricity amount and a voltage on a two-dimensional coordinate where the electricity amount is taken on an axis of abscissas and the voltage is taken on an axis of ordinates. An appropriate period such as one day, one week, one month, three months, or six months can be used as the required period. For example, the required period may be set with reference to a period in which an operation pattern of the energy storage device does not largely differ, a period in which an electricity amount calculation error when an electricity amount is calculated by integrating currents does not exceed an allowable range, and the like.

The electricity amount-voltage plots generated by the plot generation unit are divided into divided regions that are obtained by dividing by a predetermined electricity amount width. For example, the electricity amount-voltage plots drawn on a two-dimensional coordinate where an electricity amount is taken on an axis of abscissas and a voltage is taken on an axis of ordinates is zoned by a divided region obtained by dividing the electricity amount by a predetermined electricity amount width. The divided region is a vertically long rectangular region in which a horizontal direction is a predetermined electricity amount width and a vertical direction is a voltage. Some of electricity amount-voltage plots are plotted in each divided region.

The representative value calculation unit may calculate a representative electricity amount and a representative voltage representing the electricity amount and the voltage for each divided region from the electricity amount-voltage plots in each divided region. The representative electricity amount and the representative voltage may be calculated, for example, as follows.

In the first method, an average value of voltages represented by the electricity amount-voltage plots in the divided region may be set as the representative voltage, and the center of the electricity amount width of the divided region may be set as the representative electricity amount. In the second method, voltages with respect to currents in the divided region may be plotted, a voltage value when a current value of an approximate curve (for example, an approximate straight line) of the plots is 0 may be set as the representative voltage, and the center of the electricity amount width in the divided region may be set as the representative electricity amount.

The generation unit may generate a partial charge-discharge profile for a required period based on a representative electricity amount and a representative voltage for each divided region. A partial charge-discharge profile can be drawn by plotting a representative electricity amount and a representative voltage for every divided region on a two-dimensional coordinate where an electricity amount is taken on an axis of abscissas and a voltage is taken on an axis of ordinates.

With the above-described configuration, a partial charge-discharge profile in a required period (for example, a period in which an operation pattern of the energy storage device does not greatly differ, a period in which an error in calculation of an electricity amount does not exceed an allowable range and the like) can be generated.

The generation unit of the estimation device may generate a partial charge-discharge profile for a continuous period where the plurality of required periods are continuously connected based on the respective partial charge-discharge profiles in the plurality of continuous required periods.

The generation unit may generate a partial charge-discharge profile for each of a plurality of continuous required periods, and may generate a partial charge-discharge profile for a continuous period where the plurality of required periods are continuously connected based on the respective generated partial charge-discharge profiles. For example, assume a plurality of continuous required periods as a first period and a second period respectively. Even in a case where an operation pattern of the energy storage device does not significantly differ or an electricity amount calculation error at the time of calculating an electricity amount by integrating currents does not exceed an allowable range in each of the first period and the second period, there is a possibility that the operation pattern of the energy storage device may largely differ or the electricity amount calculation error exceeds the allowable range in an entire period that is the combination of the first period and the second period. In such a case, by generating a partial charge-discharge profile for a continuous period in which the first period and the second period are continuous using a partial charge-discharge profile generated in the first period and a partial charge-discharge profile generated in the second period respectively, the partial charge-discharge profile can be accurately generated without being affected by a change in an operation pattern of the energy storage device or by an electricity amount calculation error.

The estimation device may further include a profile correction unit configured to correct at least one of a first partial charge-discharge profile in one required period and a second partial charge-discharge profile in the other required period that is continuous with the one required period by moving at least one of the first partial charge-discharge profile and the second partial charge-discharge profile along an electricity amount axis on a partial charge-discharge profile such that the first partial charge-discharge profile and the second partial charge-discharge profile approach to each other. In this case, the generation unit generates a partial charge-discharge profile in the continuous periods based on correction made by the profile correction unit.

The profile correction unit performs the correction by moving at least one of the first partial charge-discharge profile and the second partial charge-discharge profile along the electricity amount axis on the partial charge-discharge profile, it is possible to make the first partial charge-discharge profile and the second partial charge-discharge profile approach each other on the partial charge-discharge profile. As a result, with respect to one period and the other period continuous to one period, even if the partial charge-discharge profiles in the respective periods are deviated from each other because of an electricity amount calculation error, for example, the deviation can be reduced so that a partial charge-discharge profile in a contact period that is longer than the required period can be generated.

The diagnostic device includes a diagnosis unit that diagnoses a full charge capacity of the energy storage device based on an entire discharge characteristic estimated by the estimation device described above.

A diagnosis method includes: a step of acquiring time-series data of a current and a voltage of an energy storage device; a step of calculating time-series data of an electricity amount based on the acquired time-series data of the current; a step of generating a partial charge-discharge profile of the energy storage device based on the acquired time-series data of the voltage and the calculated time-series data of the electricity amount; a step of estimating an entire discharge characteristic of the energy storage device based on the positive electrode monopolar characteristic and the negative electrode monopolar characteristic and the partial charge-discharge profile; and a step of diagnosing a full charge capacity of the energy storage device based on the estimated entire discharge characteristic.

The diagnosis unit of the diagnostic device diagnoses the full charge capacity of the energy storage device based on the entire discharge characteristic estimated by the estimation device. A full charge capacity (diagnostic capacity) of the energy storage device can be calculated by subtracting an electricity amount corresponding to an upper limit voltage of the entire discharge curve from an electricity amount corresponding to a lower limit voltage of the entire discharge characteristic.

With the above-described configuration, it is possible to diagnose a full charge capacity of an energy storage device in an actual operation pattern even when the energy storage device is operated in accordance with an actual operation pattern without stopping the operation of the energy storage system (or without being operated in a specific operation pattern for a capacity diagnosis).

The diagnostic device may further include: a statistical value calculation unit that calculates a statistical value of a full charge capacity over the plurality of periods by using a full charge capacity of the energy storage device diagnosed by the diagnosis unit for each period; a determination unit that determines validity or invalidity of the full charge capacity for each period diagnosed by the diagnosis unit using the statistical value calculated by the statistical value calculation unit; and a capacity calculation unit that calculates the full charge capacity of the energy storage device over a required period excluding the full charge capacity determined to be invalid by the determination unit.

The statistical value calculation unit calculates a statistical value of a full charge capacity over a plurality of periods by using the full charge capacities of the energy storage device diagnosed by the diagnosis unit for the respective periods. For example, the diagnosis unit diagnoses a full charge capacity in the period A (for example, one day or the like), and calculates a statistical value of a full charge capacity in the period B over the plurality of periods A. For example, the periods A1, A2, A3, A4, and A5 can be collectively set as the period B. The statistical value may be, for example, a moving average R of a full charge capacity and a standard deviation σ. Assuming that full charge capacities diagnosed in five periods A1 to A5 assuming Q1 to Q5, a moving average R can be obtained by an equation of R=(Q1+Q2+Q3+Q4+Q5)/5. A standard deviation σ can be obtained by an equation of σ=√{Σ(Qi−R)²/5}.

The determination unit determines validity-invalidity of a full charge capacity for each period that is diagnosed by the diagnosis unit using a statistical value obtained by calculation. In the determination of validity-invalidity, for example, when a diagnosed full charge capacity is within a range of average R+σ, it is determined that the full charge capacity is valid, and when the diagnosed full charge capacity is out of the range, it is determined that the diagnosed full charge capacity is invalid.

The capacity calculation unit calculates the full charge capacity of the energy storage device over the required period excluding the full charge capacities that are determined to be invalid. A required period C is a period longer than the period B.

As described above, even when a use state (a time ratio of a charge time, a discharge time and a pause time, an SOC range (an SOC region) or the like) of the energy storage device differs for every period, or there is a deviation for every period, the capacity diagnosis can be performed with high accuracy.

Hereinafter, embodiments of an estimation device, a diagnostic device, an estimation method and a diagnosis method will be described with reference to the drawings.

### First Embodiment

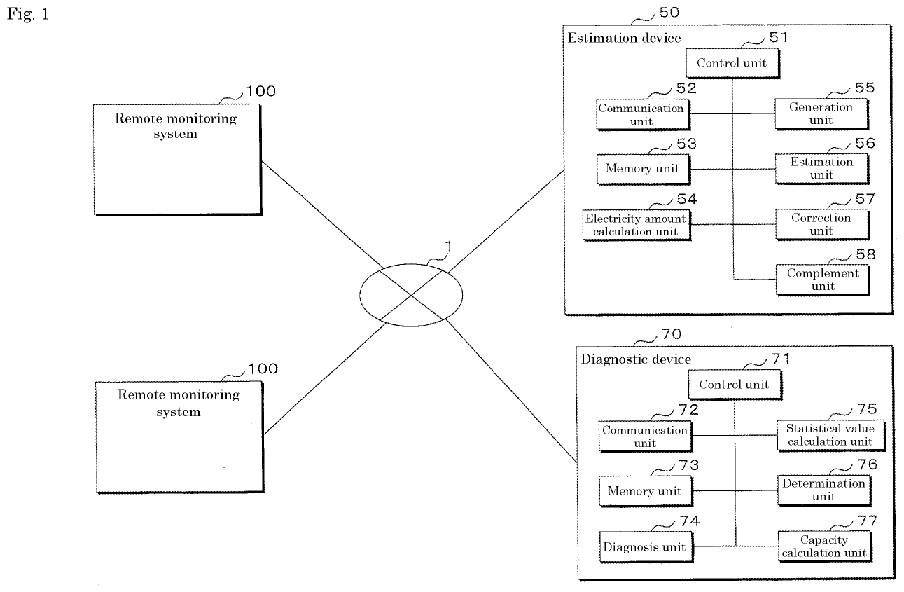

FIG. 1 is a block diagram illustrating the configuration of an estimation device 50 and the configuration of a diagnostic device 70. The estimation device 50 and the diagnostic device 70 are connected to a communication network 1. The estimation device 50 and the diagnostic device 70 may be integrated into either one of the estimation device 50 or the diagnostic device 70. A remote monitoring system 100 is connected to the communication network 1. The number of remote monitoring systems 100 may be one or three or more. Both the estimation device 50 and the diagnostic device 70 or either one of the estimation device 50 or the diagnostic device 70 may be integrated into any one of the remote monitoring systems 100. The estimation device 50 and the diagnostic device 70 will be described later.

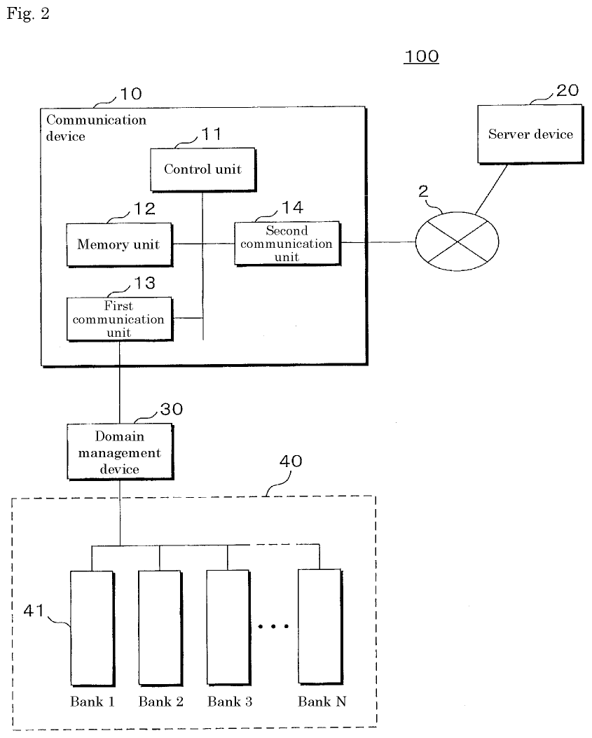

FIG. 2 is a view illustrating an entire configuration of the remote monitoring system 100. The remote monitoring system 100 includes: a communication device 10; a server device 20 that is connected to the communication device 10 via a communication network 2; a domain management device 30; and an energy storage unit (domain) 40. The energy storage unit 40 may include a plurality of banks 41. The energy storage unit 40 is, for example, housed in a battery board, and used for a thermal power generation system, a mega solar power generation system, a wind power generation system, an uninterruptible power supply (UPS), a stabilized power supply system for a railway, and the like. A portion of the energy storage unit 40 excluding a power conditioner (not illustrated) may be referred to as a storage battery system.

A business operator performs a design business, an introducing business, an operating business and a maintenance business of the energy storage system that includes the communication device 10, the domain management device 30, and the energy storage unit 40, and can remotely monitor the energy storage system using the remote monitoring system 100.

The communication device 10 includes a control unit 11, a memory unit 12, a first communication unit 13, and a second communication unit 14. The control unit 11 includes, for example, a central processing unit (CPU) and the like. The control unit 11 controls the entire communication device 10 using an incorporated memory such as read only memory (ROM), a random access memory (RAM), and the like.

As the memory unit 12, for example, a non-volatile memory such as a flash memory can be used. The memory unit 12 can store necessary information. For example, the memory unit 12 can store information obtained by processing of the control unit 11.

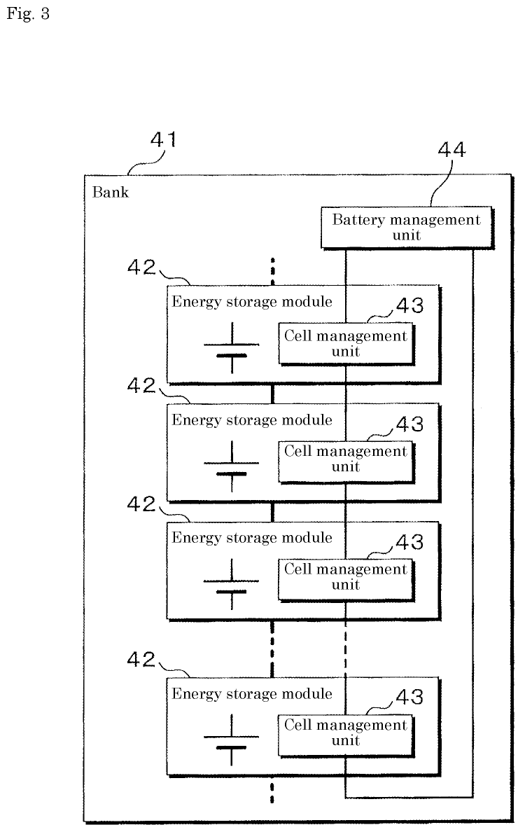

The first communication unit 13 can communicate with the domain management device 30 (or the battery management unit 44 illustrated in FIG. 3).

The second communication unit 14 can communicate with the server device 20 via the communication network 2.

The domain management device 30 transmits and receives information to and from respective banks 41 using a predetermined communication interface.

The memory unit 12 can store the operation data acquired via the domain management device 30.

The server device 20 can collect operation data of the energy storage system from the communication device 10. The operation data includes time-series data such as current data, voltage data, and temperature data of respective energy storage devices in the energy storage system. The operation data may include data on state of charge (SOC) that can be calculated from the time-series data. The server device 20 stores the collected operation data in a form that the operation data is divided for the respective energy storage devices. The server device 20 can transmit the operation data to the estimation device 50 via the communication networks 2 and 1. Note that the communication networks 1 and 2 may be formed into one communication network.

FIG. 3 is a block diagram illustrating the configuration of the bank 41. The bank 41 is formed by connecting a plurality of energy storage modules in series. The bank 41 includes a battery management unit (BMU) 44, a plurality of energy storage modules 42, cell management units (CMU) 43 that are provided to the respective energy storage modules 42, and the like.

In the energy storage module 42, a plurality of energy storage cells are connected in series. In the present specification, the “energy storage device” may be referred to as an energy storage cell, the energy storage module 42, the bank 41, or a domain where the banks 41 are connected to each other in parallel. In the present embodiment, the cell management unit 43 acquires energy storage device information relating to states of the respective energy storage cells of the energy storage module 42. The energy storage device information includes, for example, voltages, currents, temperatures, states of charges (SOCs), SOH, and the like of the energy storage cells. The energy storage device information can be repeatedly acquired at an appropriate cycle of, for example, 0.1 seconds, 0.5 seconds, 1 second, or the like. The data in which the energy storage device information is accumulated forms a part of the operation data. The “energy storage device” is preferably a rechargeable energy storage device such as a secondary battery including a lead-acid battery and a lithium ion battery or a capacitor. A part of the energy storage device may be a non-rechargeable primary battery.

The battery management unit 44 can communicate with the cell management unit 43 having a communication function via serial communication, and can acquire the energy storage device information detected by the cell management unit 43. The battery management unit 44 can transmit and receive information to and from the domain management device 30. The domain management device 30 collects the energy storage device information from the battery management units 44 of the banks belonging to the domain. The domain management device 30 outputs the collected energy storage device information to the communication device 10. In this manner, the communication device 10 can acquire the operation data of the energy storage unit 40 via the domain management device 30.

As illustrated in FIG. 1, the estimation device 50 includes a control unit 51 that controls the entire device, a communication unit 52, a memory unit 53, an electricity amount calculation unit 54, a generation unit 55, an estimation unit 56, a correction unit 57, and a complement unit 58. The control units 51 includes a central processing unit (CPU), a read only memory (ROM), a random access memory (RAM), and the like. The memory unit 53 is formed of a hard disk, a semiconductor memory or the like, and stores necessary data.

The communication unit 52 includes a communication module thus having a communication function with the diagnostic device 70 and the remote monitoring system 100 (server device 20). The communication unit 52 has a function as an acquisition unit, and acquires time-series data of currents and voltages of the energy storage devices in the remote monitoring system 100. The time-series data of the currents and the voltages is data at the time of charging electricity to the energy storage devices or at the time of discharging electricity from the energy storage devices. For example, a charge current or a discharge current does not need to be constant. A SOC (state of charge) region and a voltage region during charging and the SOC region and the voltage region during discharging may be limitative. Here, the term “limitative” means that the region does not include the entire region from an upper limit value to a lower limit value of the voltage or the SOC. The communication unit 52 acquires time-series data in an actual operation state (not in an operation stop state or not in a specific operation state for capacity diagnosis) of the energy storage devices. The time-series data may be real-time data or past history data.

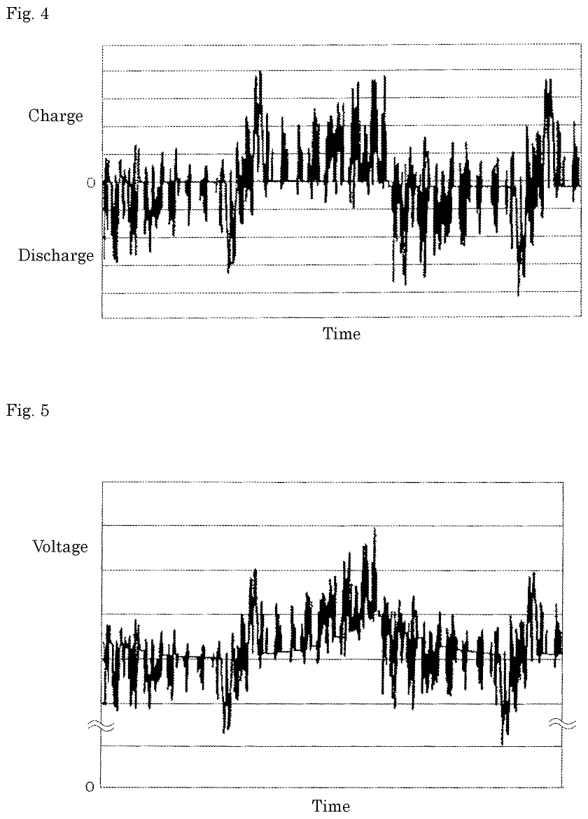

FIG. 4 is a diagram illustrating an example of current data, and FIG. 5 is a diagram illustrating an example of voltage data. In FIG. 4, a current is taken on an axis of ordinates, in which a positive side of the axis indicates a charge current, and a negative side of the axis indicates a discharge current. Time is taken on an axis of abscissas. The estimation device 50 acquires time-series current data illustrated in FIG. 4. In FIG. 5, a voltage is taken on an axis of ordinates, and time is taken on an axis of abscissas. The estimation device 50 acquires time-series voltage data illustrated in FIG. 5.

The memory unit 53 illustrated in FIG. 1 stores the time-series data acquired via the communication unit 52.

The electricity amount calculation unit 54 calculates time-series data of an electricity amount based on the time-series data of a current acquired via the communication unit 52. An electricity amount can be obtained by current integration. For example, an electricity amount Q (t) can be calculated by an equation {Q (t)=ΣI (t)·Δt}.

The generation unit 55 generates a partial charge-discharge profile of the energy storage device based on the time-series data of a voltage acquired via the communication unit 52 and the time-series data of an electricity amount calculated by the electricity amount calculation unit 54.

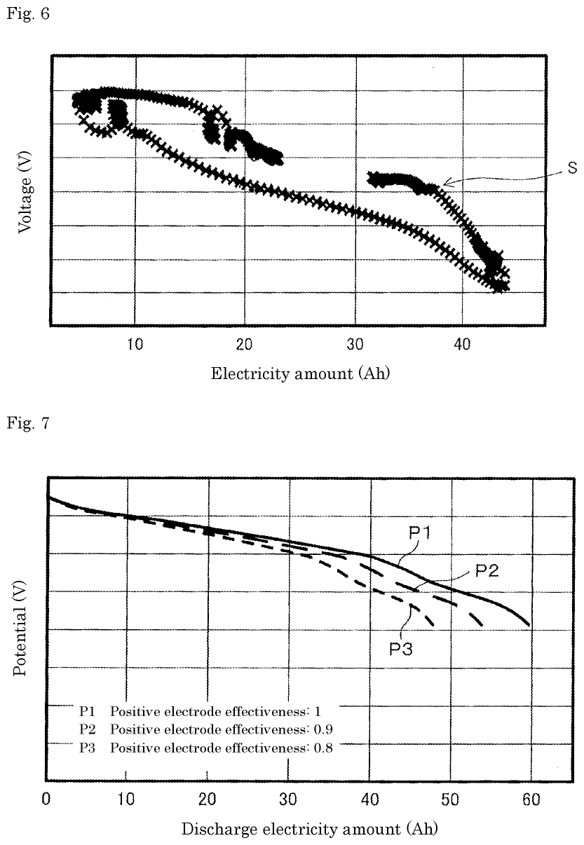

FIG. 6 is a diagram illustrating an example of a partial charge-discharge profile (a state where plots each obtained every predetermined period are superimposed). In FIG. 6, an electricity amount (Ah) is taken on an axis of abscissas, and a voltage (V) is taken on an axis of ordinates. A partial charge-discharge profile can be drawn by plotting an electricity amount calculated by the electricity amount calculation unit 54 and a voltage at a point of time when the electricity amount is obtained (the voltage corresponding to the electricity amount).

The estimation unit 56 illustrated in FIG. 1 estimates an entire discharge characteristic of the energy storage device based on a positive electrode monopolar characteristic and a negative electrode monopolar characteristic of the energy storage device and a partial charge-discharge profile generated by the generation unit 55 (see FIG. 6). The entire discharge characteristic may be, for example, a characteristic indicated by a continuous discharge curve between an upper limit voltage and a lower limit voltage set for the energy storage device, or a characteristic indicated by a continuous discharge curve between an upper limit SOC and a lower limit SOC set for the energy storage device. However, the entire discharge characteristic is not limited to such characteristics.

The correction unit 57 may correct the positive electrode monopolar characteristic such that the difference between the positive electrode monopolar characteristic and the negative electrode monopolar characteristic approaches the partial charge-discharge profile generated by the generation unit 55. The estimation unit 56 may estimate the entire discharge characteristic of the energy storage device using the corrected positive electrode monopolar characteristic.

The correction unit 57 may correct the negative electrode monopolar characteristic such that the difference between the positive electrode monopolar characteristic and the negative electrode monopolar characteristic approaches the partial charge-discharge profile generated by the generation unit 55. The estimation unit 56 may estimate the entire discharge characteristic of the energy storage device using the corrected negative electrode monopolar characteristic. Hereinafter, the positive electrode monopolar characteristic and the negative electrode monopolar characteristic will be described.

FIG. 7 is a diagram illustrating an example of correction of a positive electrode monopolar characteristic using a first parameter. The positive electrode monopolar characteristic is a characteristic indicated by a discharge curve of a positive electrode (for example, a counter electrode lithium). In the diagram where a discharge electricity amount (Ah) is taken on an axis of abscissas and a potential (V) is taken on an axis of ordinates, a positive electricity discharge curve is obtained by plotting a discharge electricity amount and a potential corresponding to the discharge electricity amount. The first parameter is a positive electrode effectiveness (also referred to as “utilization ratio”). The positive electrode effectiveness is an index indicating a usable amount of an active material in the positive electrode. In FIG. 7, three positive electrode discharge curves P1, P2, and P3 are illustrated. The positive electrode discharge curves P1, P2, and P3 correspond to positive electrode effectiveness 1, 0.9, and 0.8 respectively. When the positive electrode effectiveness is 1, the energy storage device is substantially equal to a brand new energy storage device, and the positive electrode effectiveness decreases as the deterioration progresses. As illustrated in FIG. 7, the positive electrode monopolar characteristic is corrected so as to reduce the positive electrode discharge curve in magnitude in the horizontal axis direction corresponding to the positive electrode effectiveness (first parameter).

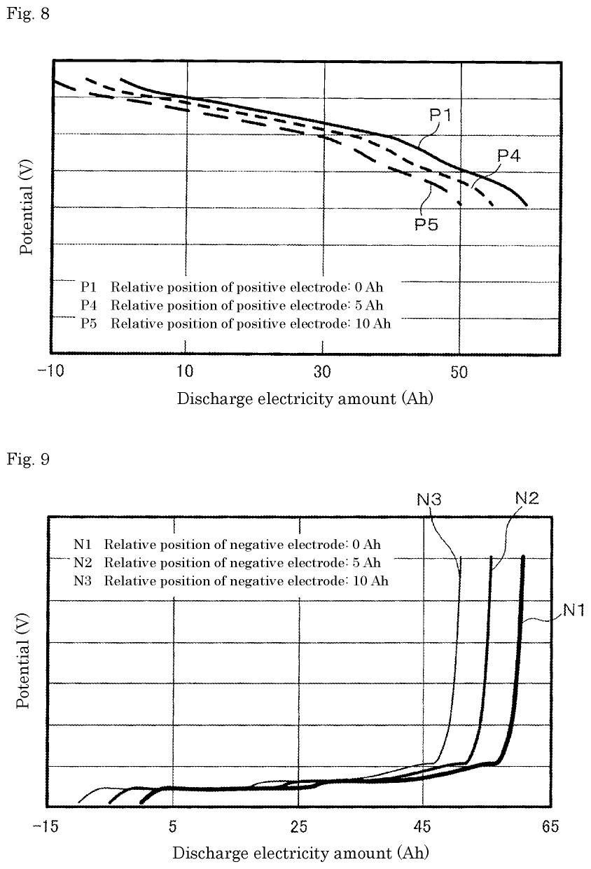

FIG. 8 is a diagram illustrating an example of correction of a positive electrode monopolar characteristic using a second parameter. The second parameter is a discharge start position of the positive electrode. The discharge start position of the positive electrode is an index indicating oxidative decomposition of the electrolytic solution. In FIG. 8, three positive electrode discharge curves P1, P4, and P5 are illustrated. The positive electrode discharge curves P1, P4 and P5 correspond to the relative positions (shifts from 0 Ah to the negative side) 0 Ah, −5 Ah, and −10 Ah of the discharge start respectively. As illustrated in FIG. 8, the positive electrode monopolar characteristic is corrected so as to make the positive electrode discharge curve translate in the lateral axis direction corresponding to a change in the relative position of the discharge start.

FIG. 9 is a diagram illustrating an example of correction of a negative electrode monopolar characteristic using a third parameter. The negative electrode monopolar characteristic is a characteristic indicated by a discharge curve of a negative electrode (for example, a counter electrode lithium). In the diagram where a discharge electricity amount (Ah) is taken on an axis of abscissas and a potential (V) is taken on an axis of ordinates, a negative electricity discharge curve is obtained by plotting a discharge electricity amount and a potential corresponding to the discharge electricity amount. The difference between a potential of the positive electrode and a potential of the negative electrode becomes a voltage of the energy storage device. The third parameter is a discharge start position of the negative electrode. The discharge start position of the negative electrode is an index that indicates the growth of a solid electrolyte interface (SEI) film. In FIG. 9, three negative electrode discharge curves N1, N2, and N3 are illustrated. The negative electrode discharge curves N1, N2 and N3 correspond to the relative positions (shifts from 0 Ah to the negative side) 0 Ah, −5 Ah and −10 Ah of the discharge start respectively. As illustrated in FIG. 9, the negative electrode monopolar characteristic is corrected so as to make the negative electrode discharge curve translate in the lateral axis direction corresponding to a change in the relative position of the discharge start.

The positive electrode monopolar characteristic, the negative electrode monopolar characteristic, and the first to third parameters may be stored in the memory unit 53.

With the provision of the above-described configuration, it is possible to bring the difference between a positive electrode monopolar characteristic and a negative electrode monopolar characteristic close to a partial charge-discharge profile.

The correction unit 57 corrects at least one of a positive electrode monopolar characteristic and a negative electrode monopolar characteristic of the energy storage device such that the difference between the positive electrode monopolar characteristic and the negative electrode monopolar characteristic approaches a partial charge-discharge profile generated by the generation unit 55. The estimation unit 56 can estimate an entire discharge characteristic from the difference between the positive electrode monopolar characteristic and the negative electrode monopolar characteristic after these monopolar characteristics are corrected.

With the above-described configuration, it is possible to estimate the entire discharge characteristic of the energy storage device based on the time-series data of a current and a voltage obtained in an actual operation state without stopping an operation of the energy storage system or without performing charging and discharging of electricity to and from the energy storage system in accordance with a specific operation pattern for a capacity diagnosis. Hereinafter, an estimation method for the entire discharge characteristic will be specifically described.

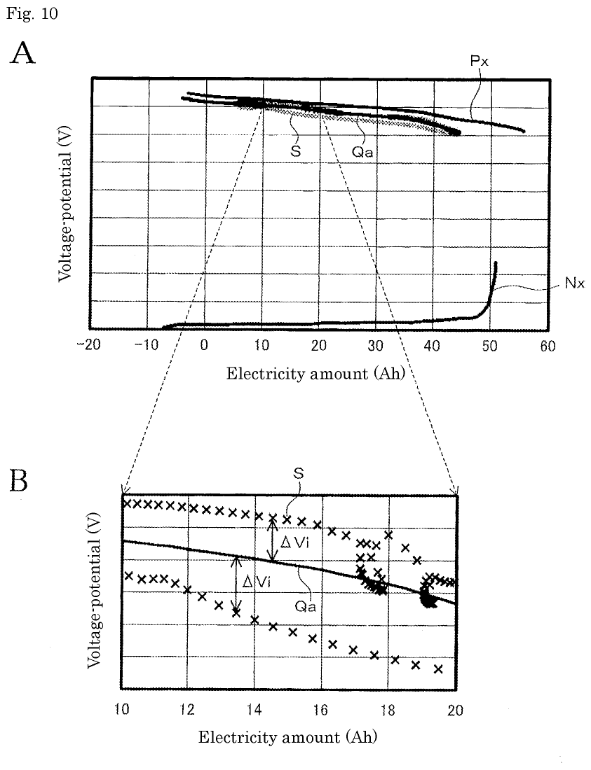

FIG. 10 is a diagram illustrating a method of estimating a portion corresponding to a partial charge-discharge profile in an entire discharge characteristic. In FIG. 10, an electricity amount (Ah) is taken on an axis of abscissas, and a voltage (V) is taken on an axis of ordinates. FIG. 10A illustrates a partial charge-discharge profile S, a positive electrode discharge curve Px, and a negative electrode discharge curve Nx. By adjusting the first parameter and the second parameter described above, the shape of a positive electrode discharge curve Px can be adjusted so that a positive electrode monopolar characteristic can be corrected. Further, by adjusting a third parameter, the shape of a negative electrode discharge curve Nx can be adjusted so that a negative electrode monopolar characteristic can be corrected.

At least one of the first to third parameters is adjusted so as to adjust at least one of the positive electrode discharge curve Px and the negative electrode discharge curve Nx. With such adjustment, it is possible to make a difference between a potential corresponding to a certain electricity amount of the positive electrode discharge curve Px and a potential corresponding to the electricity amount of the negative electrode discharge curve Nx approach a potential corresponding to the electricity amount of the partial charge-discharge profile S. The difference between the potential corresponding to a certain electricity amount on the positive electrode discharge curve Px and the potential corresponding to the electricity amount on the negative electrode discharge curve Nx is a voltage corresponding to the electricity amount on the entire discharge curve (specifically, a portion Qa corresponding to the partial charge-discharge profile S).

For example, as illustrated in an enlarged manner in FIG. 10B, the first to third parameters are obtained such that the sum of squares (ΣΔVi²) of the voltage difference ΔVi between a voltage corresponding to a certain electricity amount in the partial charge-discharge profile S and a voltage corresponding to the electricity amount in the portion Qa of the entire discharge curve corresponding to the partial charge-discharge profile S is minimized. Here, the sum of squares may treat voltages corresponding to all electricity amounts on the partial charge-discharge profile S.

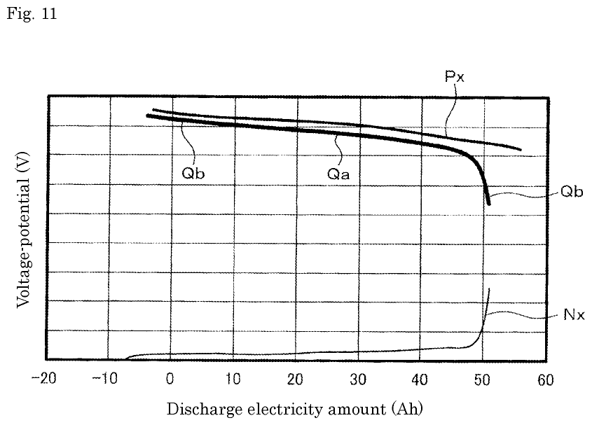

FIG. 11 is a diagram illustrating a method of estimating the entire discharge characteristic by complementing portions other than the partial charge-discharge profile. The complement unit 58 complements the entire discharge characteristic of the energy storage device based on the difference between the positive electrode monopolar characteristic and the negative electrode monopolar characteristic with respect to capacity bands other than a capacity band corresponding to a partial charge-discharge profile. As described above, by adjusting at least one of the positive electrode discharge curve Px and the negative electrode discharge curve Nx so that the difference between the positive electrode discharge curve Px and the negative electrode discharge curve Nx approaches the partial charge-discharge profile S, a discharge curve Qa can be estimated with respect to the capacity band corresponding to the partial charge-discharge profile S. With respect to the capacity bands other than the capacity band corresponding to the partial charge-discharge profile S, a discharge curve Qb is complemented based on the difference between the adjusted positive electrode discharge curve Px and the adjusted negative electrode discharge curve Nx. The entire discharge curve can be estimated by connecting the discharge curve Qa and the discharge curves Qb.

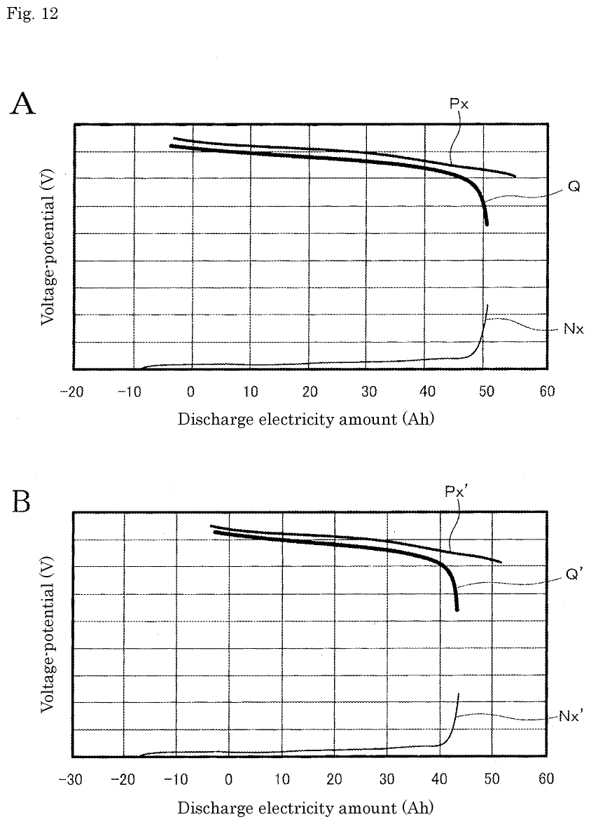

FIG. 12 is a diagram illustrating the entire discharge curve before deterioration and the entire discharge curve after deterioration. FIG. 12A shows an example of an initial entire discharge curve Q of the energy storage device at an initial stage that is estimated by the estimation device 50, and FIG. 12B shows an example of the entire discharge curve Q′ of the energy storage device after deterioration that is estimated by the estimation device 50. In FIG. 12A, the entire discharge curve Q is estimated based on the positive electrode discharge curve Px and the negative electrode discharge curve Nx which are not corrected (adjusted). By changing at least one of the first parameter to the third parameter with respect to the positive electrode discharge curve Px and the negative electrode discharge curve Nx in consideration of the deterioration of the energy storage device, as illustrated in FIG. 12B, the positive electrode discharge curve Px′ after the deterioration and the negative electrode discharge curve Nx′ after the deterioration can be obtained. The entire discharge curve Q′ after the deterioration is estimated based on the positive electrode discharge curve Px′ and the negative electrode discharge curve Nx′.

As described above, by appropriately adjusting the first parameter to the third parameter, it is possible to estimate the entire discharge characteristic compatible with the partial charge-discharge profile.

Next, the configuration of the diagnostic device 70 will be described. As illustrated in FIG. 1, the diagnostic device 70 includes a control unit 71 that controls the entire device, a communication unit 72, a memory unit 73, a diagnosis unit 74, a statistical value calculation unit 75, a determination unit 76, and a capacity calculation unit 77. The control unit 71 includes a central processing unit (CPU), a read only memory (ROM), a random access memory (RAM) and the like. The memory unit 73 is formed of a hard disk, a semiconductor memory or the like, and stores necessary data.

The communication unit 72 acquires data on the entire discharge characteristic of the energy storage device estimated by the estimation device 50.

The diagnosis unit 74 diagnoses the capacity of the energy storage device based on the entire discharge characteristic estimated by the estimation device 50.

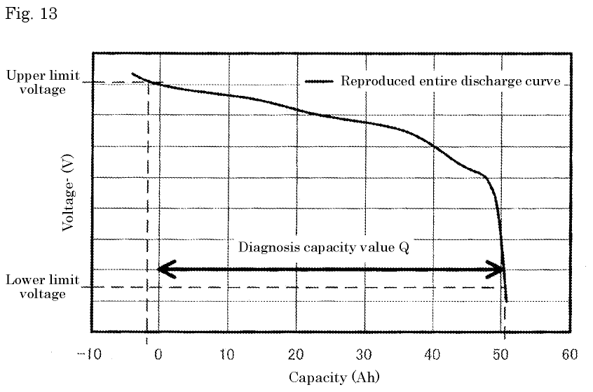

FIG. 13 is a view illustrating a first example of a diagnosis method of a full charge capacity of an energy storage device. In FIG. 13, a capacity (Ah) is taken on an axis of abscissas, and a voltage (V) is taken on an axis of ordinates. The entire discharge characteristic (reproduced entire discharge curve) estimated by the estimation device 50, is reproduced as a discharge curve that is continuous from an upper limit voltage to a lower limit voltage that are set in the energy storage device. A full charge capacity (diagnostic capacity) of the energy storage device can be calculated by subtracting the capacity corresponding to the upper limit voltage of the entire discharge curve from the capacity (electricity amount) corresponding to the lower limit voltage of the entire discharge curve.

With the above-described configuration, it is possible to diagnose a full charge capacity of an energy storage device even when the energy storage device is operated in an actual operation pattern without stopping its operation (or without being operated in a specific operation pattern for a capacity diagnosis).

A use state of the energy storage device varies corresponding to a period (for example, every day, a time zone or the like). Specifically, a time ratio of a charge time, a discharge time and a pause time, and a range of an SOC (an SOC region) during which the energy storage device is used may differ. For example, when only the percentage of the charge time is extremely large, a voltage of the discharge characteristic of the energy storage device becomes higher. In a case where there is a day where a use state is extremely biased during a relatively long period (for example, one week, one month or the like), there is a possibility that the accuracy of a capacity diagnostic value decreases. Hereinafter, a method for overcoming this point will be described.

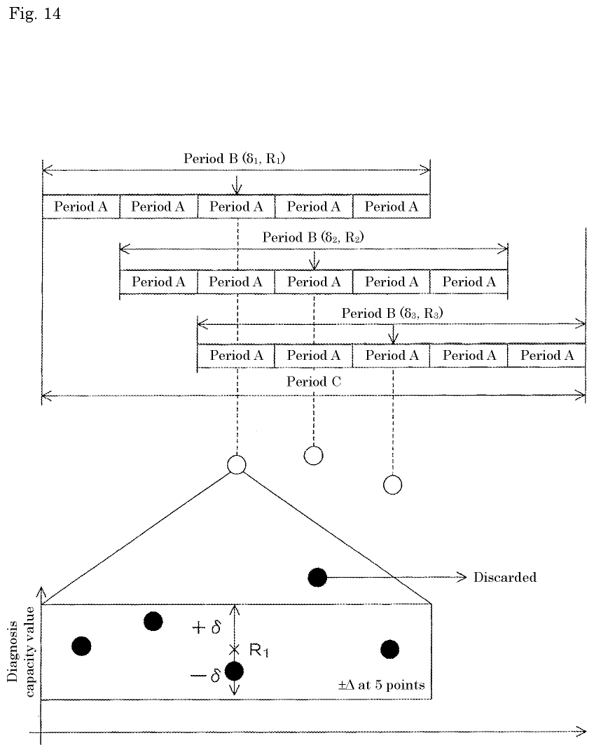

FIG. 14 is a view illustrating a second example of a diagnosis method of a full charge capacity of an energy storage device. This method is based on the premise that a full charge capacity of an energy storage device does not significantly change within about one week or within about one month. In FIG. 14, the description is made by taking a period A, a period B, and a period C as an example. The period A is, for example, a period that corresponds to one day, but may be a time zone or the like in place of one day. The period B includes a plurality of periods A. That is, a relationship of period B>period A is established. In the example of FIG. 14, five periods A are collectively referred to as a period B. A plurality of periods B are set by shifting the period B in terms of a unit of period A. The period C is a period longer than the period B. In the example illustrated in FIG. 14, the period C is a collective period consisting of seven periods A. However, the period C may be a collective period of the number of periods A that is other than seven.

The statistical value calculation unit 75 calculates a statistical value of a full charge capacity over a plurality of periods by using the full charge capacities of the energy storage device diagnosed by the diagnosis unit for the respective periods. For example, the diagnosis unit 74 diagnoses a full charge capacity in the period A, and calculates a statistical value of a full charge capacity in the period B over the plurality of periods A. The statistical value may be, for example, a moving average R of a full charge capacity and a standard deviation σ. Assuming that full charge capacities diagnosed in five periods A as Q1 to Q5, a moving average R can be obtained by an equation of R=(Q1+Q2+Q3+Q4+Q5)/5. A standard deviation σ can be obtained by an equation of σ=√{Σ(Qi−R)²/5}.

The determination unit 76 determines validity-invalidity of a full charge capacity for each period A that is diagnosed by the diagnosis unit 74 using a statistical value that is calculated by the statistical value calculation unit 75. In the determination of validity-invalidity, for example, when a diagnosed full charge capacity is within a range of average R±σ, it is determined that the full charge capacity is valid, and when the diagnosed full charge capacity is out of the range, it is determined that the diagnosed full charge capacity is invalid.

The capacity calculation unit 77 calculates the full charge capacity of the energy storage device over the required period C excluding the full charge capacities that are determined to be invalid by the determination unit 76.

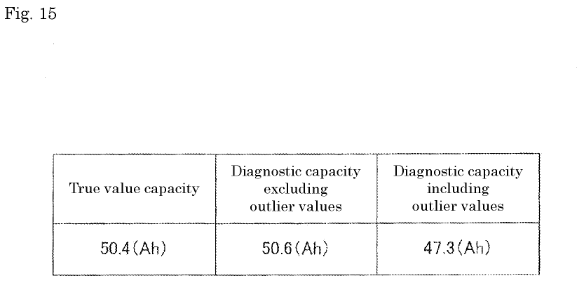

FIG. 15 is a diagram illustrating a result of a diagnostic capacity. As illustrated in FIG. 15, the true value capacity (the true value of the full charge capacity) is set to 50.4 (Ah). In a case where outliers (full charge capacities determined to be invalid) were excluded, the diagnostic capacity was 50.6 (Ah). On the other hand, in a case where the outliers (the full charge capacities determined to be invalid) were included, the diagnostic capacity (the diagnostic value of the full charge capacity) was 47.3 (Ah).

As described above, even when a use state (a time ratio of a charge time, a discharge time and a pause time, an SOC use region or the like) of the energy storage device differs for every period, or there is a deviation between the respective periods, the capacity diagnosis can be performed with high accuracy.

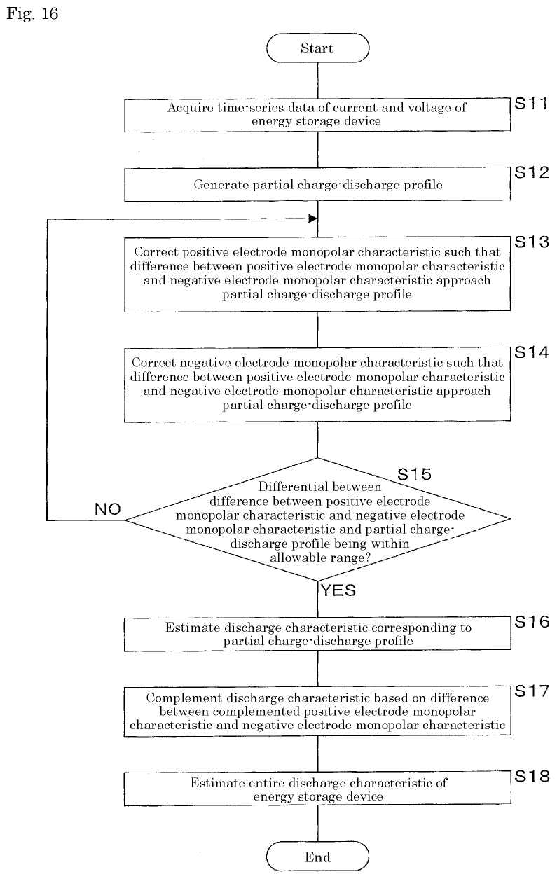

FIG. 16 is a flowchart illustrating an example of processing steps of the estimation device 50. Hereinafter, for the sake of convenience, the description is made by assuming that the subject that performs the processing is the control unit 51. The control unit 51 acquires time-series data of a current and a voltage of the energy storage device (S11), and generates a partial charge-discharge profile (S12). The control unit 51 corrects a positive electrode monopolar characteristic such that the difference between the positive electrode monopolar characteristic and a negative electrode monopolar characteristic approaches a partial charge-discharge profile (S13), and corrects the negative electrode monopolar characteristic such that the difference between the positive electrode monopolar characteristic and the negative electrode monopolar characteristic approaches the partial charge-discharge profile (S14).

The control unit 51 determines whether or not a differential between the difference between the positive electrode monopolar characteristic and the negative electrode monopolar characteristic and the partial charge-discharge profile is within an allowable range (S15). When the differential is not within the allowable range (NO in S15), the control unit 51 continues the processing in step S13 and subsequent steps. When the differential is within the allowable range (YES in S15), the control unit 51 estimates a discharge characteristic corresponding to the partial charge-discharge profile (S16).

The control unit 51 complements the discharge characteristics other than the discharge characteristic corresponding to the partial charge-discharge profile based on the difference between the corrected positive electrode monopolar characteristic and the corrected negative electrode monopolar characteristic (S17), estimates the entire discharge characteristic of the energy storage device based on the discharge characteristic corresponding to the partial charge-discharge profile and the complemented discharge characteristics (S18), and finished the processing.

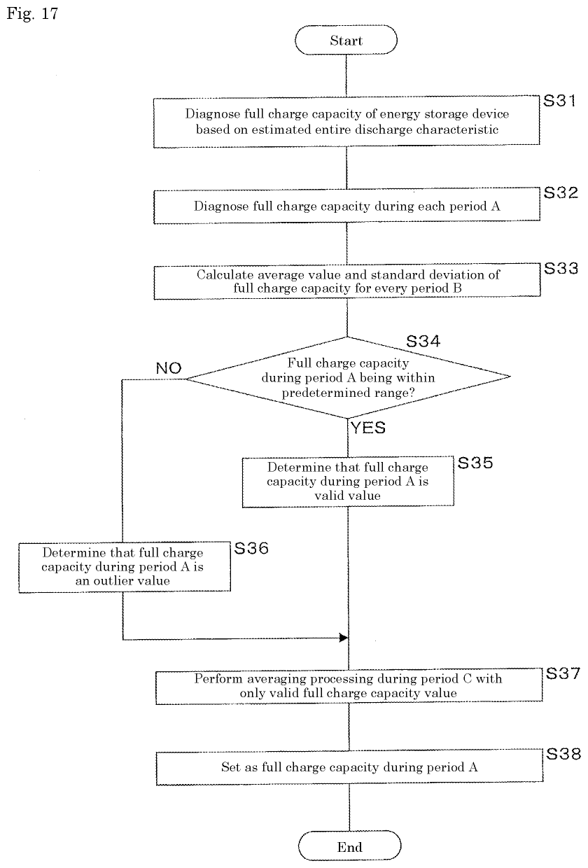

FIG. 17 is a flowchart illustrating an example of processing steps of the diagnostic device 70. Hereinafter, for the sake of convenience, the description is made by assuming that the subject that performs the processing is the control unit 71. The control unit 71 diagnoses a full charge capacity of the energy storage device based on an estimated entire discharge characteristic (S31). The control unit 71 diagnoses a full charge capacity in each period A (S32), and calculates an average value (a moving average) and a standard deviation of the full charge capacity for each period B (>period A) (S33).

The control unit 71 determines whether or not the full charge capacity diagnosed in the period A is within a predetermined range (S34). The predetermined range can be decided by the moving average and the standard deviation. When the full charge capacity diagnosed in the period A is within the predetermined range (YES in S34), the control unit 71 determines that the full charge capacity diagnosed in the period A is a valid value (S35), and performs processing in step S37 described later.

When the full charge capacity diagnosed in the period A is not within the predetermined range (NO in S34), the control unit 71 determines that the full charge capacity diagnosed in the period A is the outlier (invalid) (S36), and performs the averaging processing in the period C only with the valid full charge capacity value (S37). The control unit 71 sets the full charge capacity value to which the averaging processing is applied as the full charge capacity in the period A (S38), and finishes the processing.

The estimation device 50 and the diagnostic device 70 may be integrated into one device. For example, the electricity amount calculation unit 54, the generation unit 55, the estimation unit 56, the correction unit 57, and the complement unit 58 of the estimation device 50 may be incorporated into the diagnostic device 70.

As has been described above, according to the present embodiment, it is possible to provide a technique for performing a diagnosis of a full charge capacity without stopping an operation of the energy storage device or without operating the energy storage device in a specific operation pattern for a capacity diagnosis. The present invention is also applicable to an energy storage device after deterioration. Further, even when the deviation exists in the use state of the energy storage device for every period, it is possible to provide a highly accurate capacity diagnosis result.

### Second Embodiment

There may be a case where an operation pattern of an energy storage device (a manner how the energy storage device is used) differs depending on a period (for example, one day, one week, one month, three months, six months, or the like). In such a case, in diagnosing a full charge capacity of the energy storage device, if the operation pattern differs within a diagnosis period, there is a concern that the diagnosis accuracy is deteriorated. In the second embodiment, the description is made with respect to a method of generating a partial charge-discharge profile such that a full charge capacity can be accurately diagnosed even when an operation pattern of an energy storage device differs depending on a period. In the second embodiment, the generation unit 55 has functions of a plot generation unit, a representative value calculation unit, and a profile correction unit.

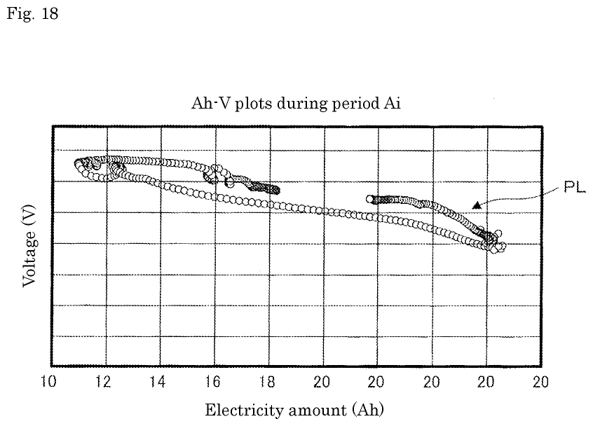

FIG. 18 is a diagram illustrating an example of electricity amount-voltage plots (Ah-V plots). In FIG. 18, an electricity amount (Ah) is taken on an axis of abscissas, and a voltage (V) is taken on an axis of ordinates. The generation unit 55 may generate electricity amount-voltage plots PL of an energy storage device over a required period (In FIG. 18, a period Ai) based on the time-series data on voltage acquired via the communication unit 52 and time-series data on electricity amount that the electricity amount calculation unit 54 calculates. The electricity amount-voltage plots (Ah-V plots) PL can be drawn, for example, by plotting time-series data on an electricity amount and a voltage on a two-dimensional coordinate where the electricity amount is taken on an axis of abscissas and the voltage is taken on an axis of ordinates. An appropriate period such as one day, one week, one month, three months, or six months can be used as the required period. For example, the required period may be set with reference to a period in which an operation pattern of the energy storage device does not largely differ, a period in which an electricity amount calculation error when an electricity amount is calculated by integrating currents does not exceed an allowable range, and the like.

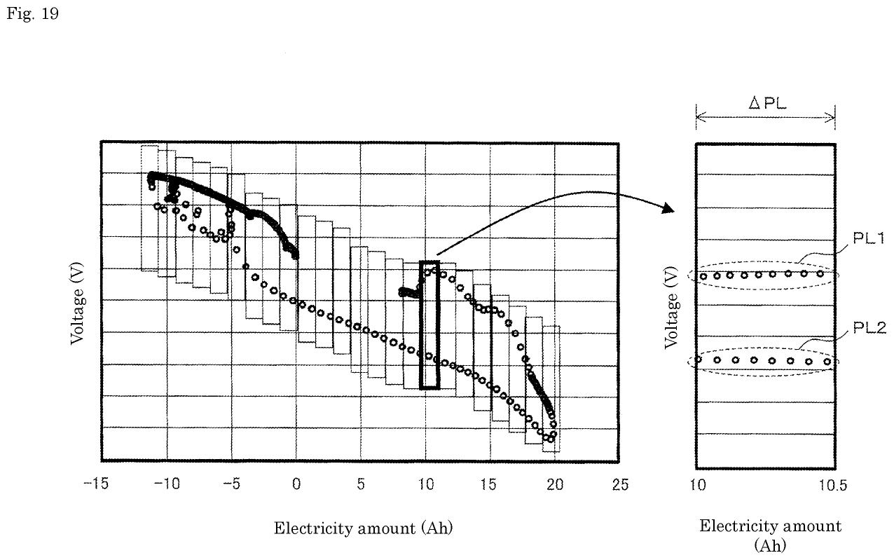

FIG. 19 is a diagram illustrating an example of divided regions. The generation unit 55 divides the generated (Ah-V plots) PL into divided regions that are obtained by dividing the generated (Ah-V plots) PL by a predetermined electricity amount width. As illustrated in FIG. 19, the (Ah-V plot) PL drawn on a two-dimensional coordinate where an electricity amount (Ah) is taken on an axis of abscissas and a voltage (V) is taken on an axis of ordinates is zoned by a divided region obtained by dividing the electricity amount by a predetermined electricity amount width (In FIG. 19, APL). The divided region is a vertically long rectangular region in which a predetermined electricity amount width APL is taken in the lateral direction, and a voltage (V) is taken in the vertical direction. Some of (Ah-V plots) PL are plotted in each divided region. In FIG. 19, the (Ah-V plots) PL1 and PL2 are plotted in a divided region APL.

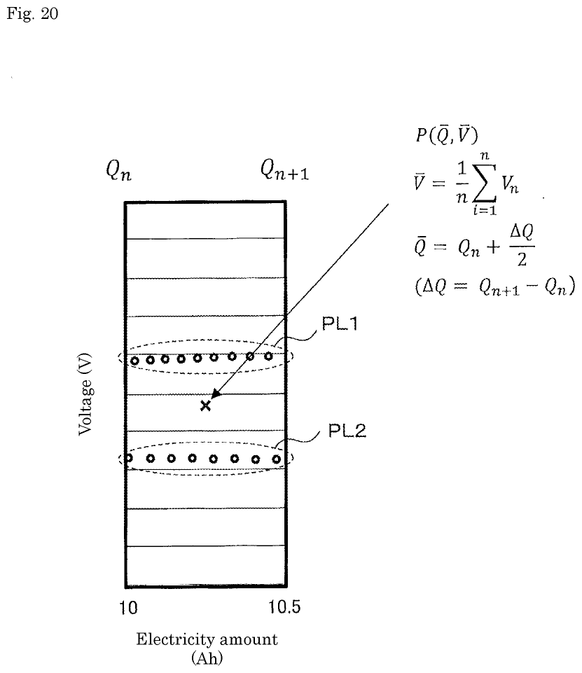

FIG. 20 is a diagram illustrating a first example of a method of calculating a representative electricity amount and a representative voltage of the divided region. The generation unit 55 may calculate a representative electricity amount and a representative voltage that represent the electricity amounts and the voltages for each divided region from (Ah-V plots) in respective divided regions. With respect to the representative electricity amount and the representative voltage, for example, an average value of voltages represented by (Ah-V plots) in the divided region may be set as the representative voltage, and the center of the electricity amount width of the divided region may be set as the representative electricity amount.

As illustrated in FIG. 20, assuming the voltages at the (Ah-V plots) PL1, PL2 in the divided region as Vi (i=1 to n), the representative voltage V (bar) may be obtained as an average of the voltages Vi. Assuming electricity amounts at both ends of the divided region as Qn, Q (n+1), the representative electricity amount Q (bar) may be a value at the center of an electricity amount width {Q(n+1)−Qn}.

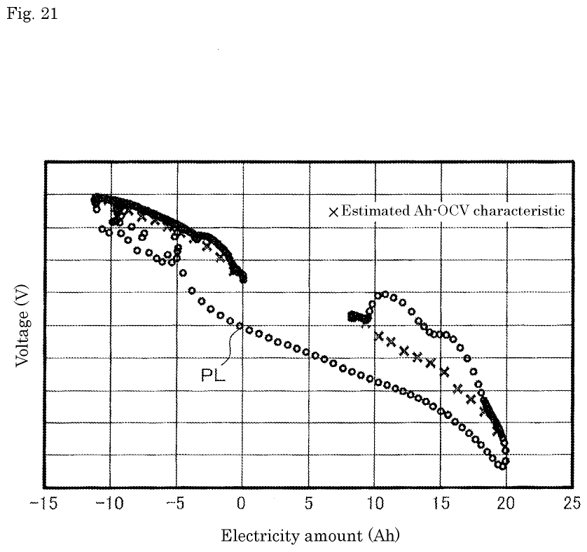

FIG. 21 is a diagram illustrating an example of a partial charge-discharge profile in a required period. The generation unit 55 may generate a partial charge-discharge profile for a required period based on a representative electricity amount Q (bar) and a representative voltage V (bar) for each divided region. As illustrated in FIG. 21, a partial charge-discharge profile (Ah-OCV characteristic) can be drawn by plotting a representative electricity amount and a representative voltage (indicated by a symbol X in FIG. 21) for each divided region on a two-dimensional coordinate where an electricity amount is taken on an axis of abscissas and a voltage is taken on an axis of ordinates.

With the above-described configuration, a partial charge-discharge profile in a required period (for example, a period in which an operation pattern of the energy storage device does not greatly differ, a period in which an error in calculation of an electricity amount does not exceed an allowable range and the like) can be generated.

The method of calculating a representative voltage V (bar) is not limited to the example illustrated in FIG. 20.

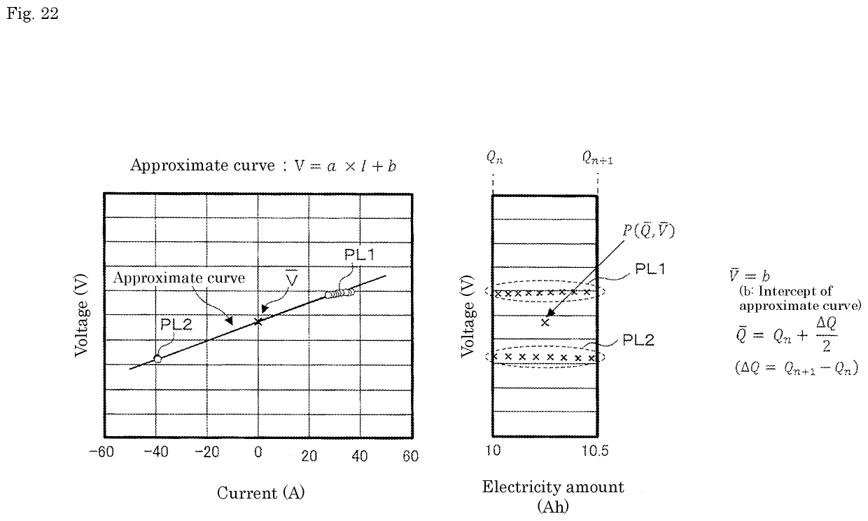

FIG. 22 is a diagram illustrating a second example of a method of calculating a representative electricity amount and a representative voltage of a divided region. As illustrated in FIG. 22, a voltage V with respect to a current I in (Ah-V plots) PL1 and PL2 in divided regions are plotted on voltage-current two-dimensional coordinates. A voltage value when a current value of a curve that approximates the plots (In FIG. 22, a straight line V=a×I+b) is 0 (that is, an intercept b) may be used as a representative voltage V (bar). Assuming electricity amounts at both ends of the divided region as Qn, Q (n+1), the representative electricity amount Q (bar) may be a value at the center of an electricity amount width {Q(n+1)−Qn}.

Next, the generation of a partial charge-discharge profile in a continuous period over a plurality of continuous required periods (an entire period over the plurality of required periods) will be described.

The generation unit 55 may generate a partial charge-discharge profile for each of a plurality of continuous required periods, and may generate a partial charge-discharge profile for a continuous period where the plurality of required periods are continuously connected based on the respective generated partial charge-discharge profiles. For example, assume a plurality of continuous required periods as a first period and a second period respectively. Even in a case where an operation pattern of the energy storage device does not significantly differ or an electricity amount calculation error at the time of calculating an electricity amount by integrating currents does not exceed an allowable range in each of the first period and the second period, there is a possibility that the operation pattern of the energy storage device may largely differ or the electricity amount calculation error exceeds the allowable range in an entire period that is the combination of the first period and the second period. In such a case, by generating a partial charge-discharge profile for a continuous period in which the first period and the second period are continuous using a partial charge-discharge profile generated in the first period and a partial charge-discharge profile generated in the second period respectively, the partial charge-discharge profile can be accurately generated without being affected by a change in an operation pattern of the energy storage device or by an electricity amount calculation error.

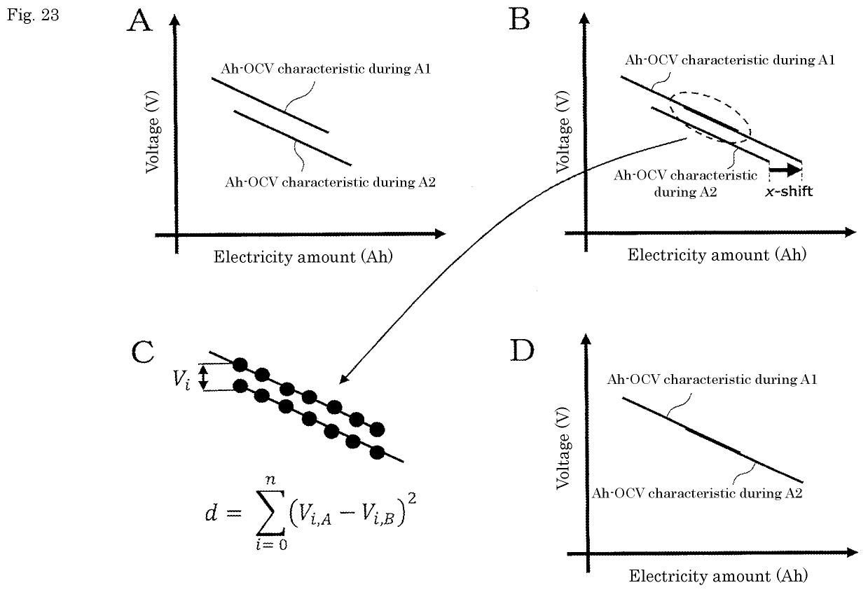

FIG. 23 is a diagram illustrating an example of the generation of a partial charge-discharge profile in a continuous period over a plurality of continuous required periods. FIG. 23A illustrates: an (Ah-OCV characteristic) (a partial charge-discharge profile) in a period A1; and an (Ah-OCV characteristic) in a period A2 continuous to the period A1. The (Ah-OCV characteristic) in the period A1 and the (Ah-OCV characteristic) in the period A2 differ depending on various factors (for example, a change in an operation pattern of the energy storage device, an electricity amount calculation error and the like). That is, the (Ah-OCV characteristic) in the period A1 and the (Ah-OCV characteristic) in the period A2 are shifted from each other on a two-dimensional coordinates of electricity amount and voltage.

The generation unit 55 performs the correction where at least one of the (Ah-OCV characteristic) (first partial charge-discharge profile) in the period A1 and the (Ah-OCV characteristic) (second partial charge-discharge profile) in the period A2 is moved along the electricity amount axis on the two-dimensional coordinate of the electricity-voltage, so that the (Ah-OCV characteristic) in the period A1 and the (Ah-OCV characteristic) in the period A2 can approach each other. In FIG. 23B, the (Ah-OCV characteristic) in the period A2 is translated along an electricity amount axis so as to bring the (Ah-OCV characteristic) in the period A2 close to the (Ah-OCV characteristic) in the period A1.

As illustrated in FIG. 23C, the residual difference d between the voltages V_{i,A} in the (Ah-OCV characteristic) in the period A1 and the voltages V_{i,B} in the (Ah-OCV characteristic) in the period A2 is minimized. With such processing, as illustrated in FIG. 23D, the (Ah-OCV characteristic) in the period A1 and the (Ah-OCV characteristic) in the period A2 may be coupled to each other so that a partial charge-discharge profile S in the period (A1+A2) may be obtained. As a result, with respect to one period and the other period continuous to one period, even if the partial charge-discharge profiles in the respective periods are deviated from each other because of an electricity amount calculation error, for example, the deviation can be reduced so that a partial charge-discharge profile in a contact period that is longer than the required period can be generated. In the example illustrated in FIG. 23, the description is made with respect to two continuous periods. However, a partial charge-discharge profile can be generated substantially in the same manner even when three or more required periods are continuous.

With respect to the partial charge-discharge profile generated in the second embodiment, the entire charge-discharge characteristic of the energy storage device can be estimated by performing substantially the same processing as the processing performed in the first embodiment. In the same manner, a full charge capacity of the energy storage device can be diagnosed based on the estimated entire discharge characteristics.

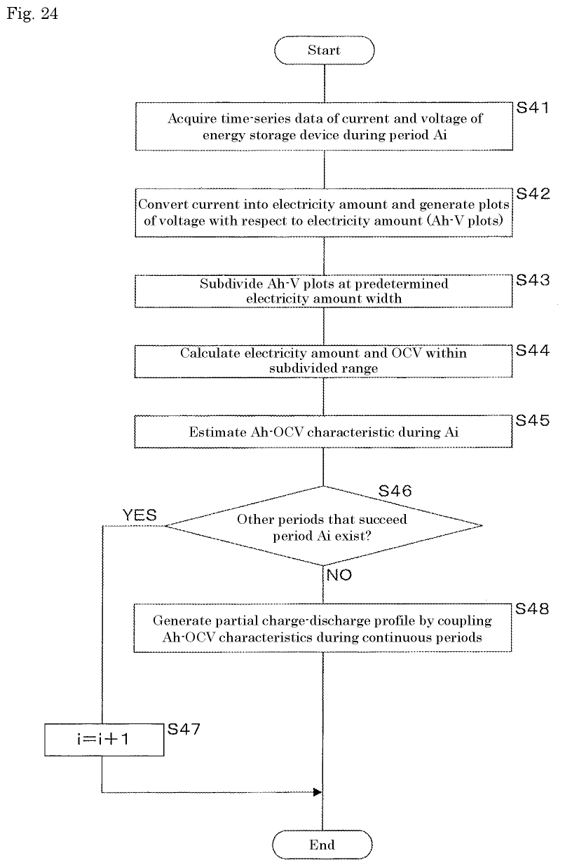

FIG. 24 is a flowchart illustrating processing steps for generating a partial charge-discharge profile according to the second embodiment. The control unit 51 acquires time-series data of currents and voltages of the energy storage device in the period Ai (S41), integrates the acquired time-series data of the currents and converts the integrated time-series data of the currents into time-series data of an electricity amount, and generates plot (Ah-V plots) of voltages with respect to the electricity amount (S42). The (Ah-V plots) are the plots illustrated in FIG. 18.

The control unit 51 subdivides (Ah-V plots) into divided regions at a predetermined electricity amount width (S43). The subdivision of (Ah-V plots) is the subdivision illustrated in FIG. 19. The control unit 51 calculates an electricity amount and an OCV in the subdivided divided region (S44). Here, as illustrated in FIG. 20 or FIG. 22, a representative electricity amount and a representative voltage for each divided region are calculated.

The control unit 51 estimates an (Ah-OCV characteristic) in the period Ai based on the representative electricity amount and the representative voltage for each divided region (S45). The (Ah-OCV characteristic) in the period Ai is the (Ah-OCV characteristic) illustrated in FIG. 21. The control unit 51 determines the presence or absence of another period that is continuous to the period Ai (S46), and in a case where there is another period (YES in S46), adds 1 to i (S47), and continues the processing in step S41 and in subsequent steps that follow step S41.

When there is no other period (NO in S46), in step S45, the control unit 51 couples the (Ah-OCV characteristics) of the respective continuous periods Ai obtained so far so as to generate a partial charge-discharge profile for the continuous periods (S48), and finishes the processing. The processing in step S48 is performed in accordance with steps exemplified in FIG. 23.

As described above, according to the second embodiment, even when the way of using the energy storage device differs for each period, the difference in (Ah-OCV characteristic) of the energy storage device for each period can be corrected so as to generate a partial charge-discharge profile in a continuous period over a plurality of periods. Accordingly, a diagnosis accuracy of a full charge capacity of the energy storage device can be enhanced.

The embodiment has been disclosed for an exemplifying purpose in all respects and is not limitative. The scope of the present invention is defined by the claims, and includes all modifications equivalent to the present invention within the meaning and the scope of the claims.

1. An estimation device comprising:
an acquisition unit configured to acquire time-series data of a current and a voltage of an energy storage device;
an electricity amount calculation unit configured to calculate time-series data of an electricity amount based on the time-series data of the current acquired by the acquisition unit;
a generation unit configured to generate a partial charge-discharge profile of the energy storage device based on the time-series data of the voltage acquired by the acquisition unit and the time-series data of the electricity amount calculated by the electricity amount calculation unit; and
an estimation unit configured to estimate an entire discharge characteristic of the energy storage device based on the partial charge-discharge profile.

2. The estimation device according to claim 1, wherein the estimation unit is configured to estimate the entire discharge characteristic of the energy storage device based on a positive electrode monopolar characteristic and a negative electrode monopolar characteristic of the energy storage device and the partial charge-discharge profile.

3. The estimation device according to claim 2, comprising a correction unit configured to correct the positive electrode monopolar characteristic and/or the negative electrode monopolar characteristic such that a difference between the positive electrode monopolar characteristic and the negative electrode monopolar characteristic approaches the partial charge-discharge profile.

4. The estimation device according to claim 1, comprising a complement unit configured to complement the partially obtained entire discharge characteristic of the energy storage device.

5. The estimation device according to claim 1, further comprising:
a plot generation unit configured to generate electricity amount-voltage plots of the energy storage device over a required period based on time-series data of a voltage acquired by the acquisition unit and time-series data of an electricity amount calculated by the electricity amount calculation unit; and
a representative value calculation unit configured to calculate a representative electricity amount and a representative voltage representing an electricity amount and a voltage in each of divided regions obtained by dividing the electricity amount-voltage plots generated by the plot generation unit by a predetermined electricity amount width,
wherein the generation unit is configured to generate a partial charge-discharge profile for the required period based on the representative electricity amount and the representative voltage for each of the divided regions calculated by the representative value calculation unit.

6. The estimation device according to claim 5, wherein the generation unit is configured to generate a partial charge-discharge profile for a continuous period where the plurality of required periods are continuously connected based on the respective generated partial charge-discharge profiles in a plurality of continuous required periods.

7. The estimation device according to claim 6, comprising a profile correction unit configured to correct at least one of a first partial charge-discharge profile in one required period and a second partial charge-discharge profile in the other required period that is continuous with the one required period by moving the at least one of the first partial charge-discharge profile and the second partial charge-discharge profile along an electricity amount axis on a partial charge-discharge profile such that the first partial charge-discharge profile and the second partial charge-discharge profile approach to each other,
wherein the generation unit is configured to generate a partial charge-discharge profile in the continuous periods based on correction made by the profile correction unit.

8. A diagnostic device according to claim 1, comprising a diagnosis unit configured to diagnose a capacity of the energy storage device based on the entire discharge characteristic estimated by the estimation device.

9. The diagnostic device according to claim 8, comprising:
a statistical value calculation unit configured to calculate a statistical value of a full charge capacity over the plurality of periods by using a full charge capacity of the energy storage device diagnosed by the diagnosis unit for each period;
a determination unit configured to determine validity or invalidity of the full charge capacity for each period diagnosed by the diagnosis unit using the statistical value calculated by the statistical value calculation unit; and
a capacity calculation unit configured to calculate the full charge capacity of the energy storage device over a required period excluding the full charge capacity determined to be invalid by the determination unit.

10. An estimation method comprising:
acquiring time-series data of a current and a voltage of an energy storage device;
calculating time-series data of an electricity amount based on the acquired time-series data of the current;
generating a partial charge-discharge profile of the energy storage device based on the acquired time-series data of the voltage and the calculated time-series data of the electricity amount; and
estimating an entire discharge characteristic of the energy storage device based on the partial charge-discharge profile.

11. A diagnosis method comprising:
acquiring time-series data of a current and a voltage of an energy storage device;
calculating time-series data of an electricity amount based on the acquired time-series data of the current;
generating a partial charge-discharge profile of the energy storage device based on the acquired time-series data of the voltage and the calculated time-series data of the electricity amount;
estimating an entire discharge characteristic of the energy storage device based on the partial charge-discharge profile; and
diagnosing a full charge capacity of the energy storage device based on the estimated entire discharge characteristic.
